(19) United States
(12) Patent Application Publication
(10) Pub. No.: US 2006/0091491 A1
(43) Pub. Date: May 4, 2006

(54) Optical detector and method of producing an arrangement of multiple semiconductor layers

(76) Inventors: Gerd Muehlnikel, Backnang (DE); Klaus Hirche, Waiblingen (DE); Martin Warth, Schwaikheim (DE)

Correspondence Address: STRIKER, STRIKER & STENBY, 103 East Neck Road, Huntington, NY, 11743, US

(21) Appl. No.: 11/273,427

(22) Filed: Nov. 14, 2005

Related U.S. Application Data
(62) Division of application No. 10/056,314, filed on Jan. 24, 2002.

(30) Foreign Application Priority Data
Jan. 31, 2001 (DE) 101 04 015.6

(51) Int. Cl. H01L 31/105; H01L 21/00

(52) U.S. Cl. 257/458; 257/436; 438/48; 257/448; 257/457; 438/98; 257/459

(57) ABSTRACT

An optical detector with an arrangement of several semiconductor layers has at least one zone absorbing in a predetermined wavelength region, at least one zone which is at least partially light-permeable in the predetermined wavelength region, one semiconductor layer which is absorbing in the predetermined wavelength region, a semiconductor layer which is located under the first mentioned semiconductor layer and is at least partially light-permeable in the predetermined wavelength region, the at least one light-permeable zone is formed as an interruption in the absorbing semiconductor layer, and a throughgoing doping provided on an upper surface of the absorbing semiconductor layer which surrounds the interruption and at least a part of an upper surface of the at least partially light-permeable semiconductor layer, wherein, the optical detector is produced by a new method and used for various applications.

### BACKGROUND OF THE INVENTION

The present invention relates to an optical detector with an arrangement of multiple semiconductor layers with at least one zone absorbing in a predetermined wavelength region and at least one zone which is at least partially light permeable in the predetermined wavelength region, wherein a semiconductor layer in the predetermined wavelength region is absorbing and the semiconductor layer located under it is at least partially light permeable in the predetermined wavelength region, and wherein the at least one light permeable zone is realized by an interruption of the absorbing semiconductor layer.

The invention also relates to a method for producing an arrangement of multiple semiconductor layers with at least one zone absorbing in a predetermined wavelength region and at least one zone which is at least partially light permeable in the predetermined wavelength region, wherein a semiconductor layer in the predetermined wavelength region is absorbing and the semiconductor layer located under it is at least partially light permeable in the predetermined wavelength region, and at least one light permeable zone is realized by an interruption of an absorption semiconductor layer.

Such optical detectors and methods are known. For example they are known in optical position-dependent detectors which have an integrated photo diode arrangement. Such optical detectors have one or several active zones, and they have a region in which they are at least transparent in a predetermined optical wavelength region or approximately transparent. The term “active zone” is here used to identified a region, in which the impinging light is absorbed and converted into a photocurrent.

FIGS. 1-5 show examples of semiconductor layer arrangements in accordance with the prior art in different views. FIG. 1 is a plan view of a part of a four-quadrant detector. This four-quadrant detector has in its center a transparent zone 122. The beam which impinges in the center of the detector or a predetermined part of the optical power of the beam passes the detector undampened or approximately undampened. When the beam position deviates from the center of the detector, the beaming light is detected in one of the outer sectors of the four-quadrant detector. The detection of the light impinging on the outer sectors is performed by producing a photocurrent. For this purpose the regions 150 of the absorbing layer 120 are p-doped.

FIG. 2 is a view showing a section through the arrangement of FIG. 1, taken along the line A-A′ in FIG. 1. In FIG. 2 the arrangement of different layers and the p-doped regions 150 can be recognized.

An n-doped InP layer 112 is arranged on an n⁺-doped substrate layer 110 of InP. An i-InGaAs layer 114 follows the layer 112. An InP layer is arranged above the layer 114 and has p-doped regions 150. The p-doped regions 150 penetrate also into the i-InGaAs layer 114. FIG. 2 shows a corresponding arrangement for a wavelength of 1064. The layers of InP 110, 112 and 116 are transparent for the light of this wavelength. The InGaAs layer 115 to the contrary is an absorbing layer. An interruption 124 is formed in the absorbing layer 114 and the InP layer 116 located on it, for providing in the layer structure a central light-permeable region. The interruption 116 with the radius c defines the light-permeable zone 122 of the shown optical detector.

Because of the doping of the different layers, the arrangement has the property of a pin-diode with an intrinsic layer 114. In the space charge zone formed in the intrinsic layer 114, as identified with a broken line, an especially effective conversion of the absorbed light into a photocurrent occurs. It is desired to keep the distance a between the space charge zone and the applied permeable zone 122 as small as possible. In other words it is desired to reduce a “dead zone”. The minimal obtainable distance a, in combination with the minimal obtainable distance b depends on several factors.
1. Safety distance in connection with a mask technique or a structuring which depend on the manufacture play a role. The sum of the variations of underdiffusion and underetching and the maximum adjustment error of the mask, at typical layer thickness in InP/InGaAs material system are estimated to be approximately 5 μm. The etching can be compensated by corresponding guidance during the mask layout. The variants to be expected occur as additionally required safety distances. Since the active, or in other words the absorbing and the transparent regions are produced with two different mask layers, additionally an adjustment error can occur.
2. Furthermore, an influence of upper surface condition takes place. Upper surface condition on the flanks of the absorbing regions 114, 120 lead to a band bending in the interior of the semiconductor, or in other words in FIG. 1 in the InGaAs layer 114. The border of the space charge zone identified with a broken line must be located outside of this region. The width of the zone InGaAs with a background doping of 10¹⁴ cm⁻³ can be located approximately at 3.4 μm. With a background doping of 10³ cm⁻³ the width of the zone can be located approximately at 10.6 μm, wherein this values are dependent on the nature of the upper surface condition.
3. Furthermore a variation of the lateral expansion of the space charge zone can occur. It depends also on the variation of the background doping and bias voltage. Critical value here is again the fluctuation width to be expected. The expectancy value (average value) alone can be compensated by a corresponding guidance in the mask layout. With values for the background doping in the region of 10¹³ cm⁻¹³-10¹⁵ cm⁻³ it starts from a variation greater than 5 μm.

In general, it is accepted that the above mentioned effects 2 (influence of upper surface condition) and 3 (variation of the lateral expansion of the space charge zone) overweighs the fact 1 (safety distances dependent on manufacture). As a whole, its start from a minimal effective width a of 10 μm to 20 μm at a realization in the InP/InGaAs/InGaAs material system in accordance with FIG. 1 or FIG. 2. The effective obtained width of the dead zone A is subjected to significant fluctuations in the realization for the above mentioned reasons.

For further illustration of the layer structure shown in FIGS. 1 and 2, FIG. 3 illustrates a section taken along the line B-B1 in FIG. 1. Three layers n⁺-InP 110, n-InP 112, i-InGaAs 114 and InP 116 with the p-doped layers 150 can be seen here. In the region of this layer the layer arrangement is absorbent in a throughgoing fashion.

FIG. 4 shows a further semiconductor arrangement, which corresponds to the arrangement of FIG. 2 up to the design of the light permeable region. In the embodiment of FIG. 4 the light-permeable region is formed as a throughgoing opening 134. In such an arrangement the dead zone is also greater than desired.

FIG. 5 shows a further embodiment of an optical detector, wherein here however silicon is used as a semiconductor material. The illustration shows a section taken along the line A-A1 in FIG. 1. The illustration in FIG. 1 is not limited to the layer arrangement shown in FIG. 2 and the materials mentioned in the description. In FIG. 5 a silicon layer 118 is provided with p-doped zones 150. The transparent region with the radius c is realized in the arrangement of FIG. 5 by a throughgoing opening 134. The distance between the p-doped region 150 and the light-permeable region realized as the throughgoing hole 134 is again identified with B. The region identified with the size a is again the dead zone of the detector.

A known advantage of the material system ImP/ImGaAsP/InGaAs of FIG. 2 as opposed to silicon of FIG. 5 is that the value of the required space charge zone and thereby the layers thickness in the layer thickness in the InGaAs relative to silicon is smaller by size orders.

For reduction of upper surface leak current it is also possible to use the arrangements which for example are shown in FIGS. 6 and 7. The arrangement shown in FIG. 6 substantially corresponds to the arrangement shown in FIG. 2. In addition a so-called “guard” ring structure is arranged around the interruption 124, or in other words an additional diffusion zone which is electrically separated from the active zone is provided. The guard ring 152 is realized by a p-doping around the interruption 124. The space consumption for the resulting dead zone a for such a structure is located however in the size order of 10 μm-20 μm.

In FIG. 7 an arrangement which is similar to the arrangement of FIG. 6 is shown. Here however the transparent region is realized by a throughgoing opening 134.

It is also possible to use guard-ring structures with silicon. Here, in view of the minimization of the dead zone, it should be considered as difficult that the width of the space charge zone is very high, for example greater than 100 μm. The guard ring structure can have a width in the region of greater than 50 μm.

### SUMMARY OF THE INVENTION

Accordingly, it is an object of the present invention to provide an optical detector and a method of producing the same, which avoids the disadvantages of the prior art.

In keeping with these objects and with others which will become apparent hereinafter, one feature of the present invention resides, briefly stated, in an optical detector in which the upper surface of the absorbing semi conductor layer which surrounds the interruption and at least a part of the upper surface of the at least partially light-permeable semiconductor layer has a throughgoing doping.

In this way it is possible to maintain a very small transition region between the absorbing and transparent zones. A generation of charge carrier by absorption of light in the inventive arrangement can occur in a flank region of the interruption. The at least partially permeable zones adjoin directly the flank region. The effective transition region can be limited thereby substantially to the penetration depth of the doped regions and therefore can be smaller than 10 μm. Typical values are located at 0.5 μm-1 μm.

As a further advantage it should be mentioned that in comparison with the prior art, the width of the transition region to be expected is substantially reproducible and is located within the range of the variance of the penetration depth of the diffusion. It is possible to define the absorbing zone and at least partially light-permeable zone in a single mask step, with which the absorbing layer is removed in the region, in which the light-permeable zone must be produced. Thereby the at least partially light-permeable region for example for circular structures has no eccentricity relative to the inner limit of the absorbing region.

Preferably the absorbing semiconductor layer is InGaAs and the at least partially light-permeable semiconductor region is InP. Thereby the detector can be used with an optical wavelength between 900 nm and 1200 nm. In this wavelength region the thickness of the absorption layer is maintained small, for example smaller than 5 μm, and no throughgoing opening is required is required. Moreover, the absorption layer must be however locally removed. The carrier substrate of InP is transparent for optical wavelength above 900 nm.

Preferably, the throughgoing doping is a p-doping and the at least partially light-permeable semiconductor layer is n-doped. Thereby the arrangement operates in accordance with the principle of a pin-diode, wherein a weakly doped inner layer is arranged between a p-layer and an n-layer. With such a structure a high light intensity is absorbed in the region between the p-and n-layer. A pin-structure has the further advantage relative to a conventional pn-transition, in that the p-and n-regions have a greater distance from one another. Finally, the capacity of the diode is smaller, that leads to a higher response speed.

Preferably two at least partially light-permeable semiconductor layers are provided with different doping concentrations. A strongly doped layer is still provided as a supporting substrate, while a weaker doped layer forms the upper n-doped layer, in which partially the throughgoing p-doped region penetrates.

Also it can be useful when the upper surfaces of the arrangement of several semiconductor layers is provided at least partially with an anti-reflection layer. Such an anti-reflection layer reduce the losses by reflection, whereby they can be applied on the front side and the back side of the optical detector.

The invention is formed in advantageous manner so that a p-contact is provided on the throughgoing p-doping, and an n-contact is provided on the n-doped partially light-permeable semiconductor layer. The region of the p-doped throughgoing layer can serve thereby for application of an electrical contact, while the rear side or in other words the substrate side of the semiconductor arrangement is used for applying an n-contact. In accordance with the prior art, for pin-diodes the n contact can be also applied on the upper surface.

It is useful when the at least partially light-permeable semiconductor layer is thinned. This can be desirable when special requirements to the quality of the optical transparency are applied, for example for providing a low optical wave front error. In this case the substrate from the rear side can be thinned up to a smaller thickness from a thickness of 350 μm to 50 μm.

For improving the transparency, it can be also useful when the throughgoing opening in the at least partially light-permeable semiconductor layer is provided in the region of the interruption of the first absorbing semiconductor layer. For producing such a throughgoing opening, a wet or dry etching structuring or a laser cutting technique can be utilized. The etching can be performed from the front side or from the rear side of the semiconductor arrangement.

It is also useful when at least partially conductive zone or zones and the absorbing zone or zones are circular-symmetrical. Such an arrangement is suitable for example for the adjustment of different optical instruments, in which an exact orientation relative to an optical axis is required.

It can be also useful if the at least partially light-permeable zone or zones and the absorbing zone or zones have an elongated form. Such slot arrangements With the inventive low dead zone are especially suitable for measuring-technical applications.

The present invention also deals with a method, in which the interruption of the absorbing semiconductor layer is performed by a local removal of the absorbing layer, and a throughgoing doping is introduced into an upper surface of the semiconductor layerwhich surrounds the interruption and at least a part of the upper surface of the at least partially light-permeable semiconductor layer.

In this manner an arrangement can be produced, which has the inventive advantages. In particular, the transition region within the absorbing and transparent zones can be maintained very small, and an absorption of light in the arrangement produced in accordance with the present invention can take place also in the flank region of the interruption. The method in accordance with the present invention when compared with the prior art can be produced with a substantially reproducible width of the transition region since within the range of the variance the penetration depth of the diffusion is located within the range of the variance.

The inventive method is reproduced in a special advantageous manner in that the local removal of the absorbing layer is performed in a first mask step, and the doping is performed in a second mask step. It is especially advantageous that the exact mask layer in the second step is not critical for the definition of the photo-sensitive region.

Preferably, in accordance with the present invention the doping is performed by selective diffusion. Thereby with respect to the thickness of the doping a process which is good to handle is provided.

The method can be performed also in that the at least partially light-permeable semiconductor layer is thinned. This can be desired when special requirements are applied to the quality of the optical transparency, for example the requirement of a low optical wave front error. In this case the substrate can be thinned from the rear side to a smaller thickness starting from a thickness of 350 μm to a thickness of 50 μm.

For the same reasons it can be useful when the throughgoing opening is introduced in at least partially conductive semiconductor layer in the region of the interruption of the absorbing semiconductor layer. For producing such a throughgoing opening, a wet or dry etching structuring or a laser cutting technique can be used. The etching can be performed from the front side or from the rear side of the semiconductor arrangement. Preferably, the throughgoing opening is introduced by etching process. Thereby a throughgoing opening with a defined construction can be produced.

It can be also useful when the throughgoing opening is formed by a laser cutting technique. Also, a fluid defined structure is formed in this way.

In accordance with a preferable further embodiment of the invention, the upper surface of the arrangement of several semiconductor layers is provided at least partially with an antireflection layer. Such antireflection layers reduce the losses by reflection, and can be applied on the front side and the rear side of the optical detector.

It is especially advantageous when an inclination of flanks in the region of interruption is influenced by a crystal orientation and/or structuring process. In this manner it is possible to impart to the arrangement different properties, depending on the special tasks of the optical detector.

In a preferable embodiment of the invention, the method is performed so that InGaAs is used as absorbing semiconductor layer, and InP is used as at least one partially light-permeable semiconductor layer. Thereby the detector is usable preferably at the optical wavelength between 900 nm and 1200 nm. In this wavelength region the thickness of the absorbing layer can be maintained local for example smaller than 5 μm and no throughgoing opening is needed. Furthermore, the absorption layer must be however removed locally. The supported substrate of InP is transparent for optical wavelength above 900 nm.

It is of a specially advantage that a p-contact is applied on the throughgoing p-doping, and an n-contact is applied on the n-doped partially light-permeable semiconductor layer. The region of the p-doped throughgoing layer can serve thereby for applying an electrical contact, while the rear side, or in other words the substrate side, of the semiconductor arrangement can be used for applying an n-contact. In accordance with the prior art for pin-diodes the n-contact can be applied on the upper surface.

Special advantages of the inventive arrangement are pronounced in their use for space applications. In particular such an application can be advantageous in connection with the communication of two satellites.

The present invention is based on the surprising determination that with the inventive throughgoing doping of a region around the light-permeable interruption the “dead zone” between transparent and absorbing regions can be very small, and can be maintained reproducible with respect to its width. Further advantages reside in that the separation of the light-permeable zone and the absorbing zone is selfadjusting. The advantage when compared with silicon arrangements is that the optically absorbing layers because of their lower thickness can be etched with lower expenses and greater accuracy in a selected way. Also it should be mentioned that the “guard” ring structures or in other words additional diffusion zones which are electrically separate from the active zone, between the opening region and the active zone are superfluous.

The novel features which are considered as characteristic for the present invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a plan view of a detector in accordance with the present invention;

FIG. 2 is a cross-section in a plan identified as A-A′ in FIG. 1, of a first embodiment of the prior art;

FIG. 3 is a section view in a plan identified as B-B′ in FIG. 1, of a first embodiment of a prior art;

FIG. 4 is a section view of a plan identified as A-A′ of FIG. 1 of a second embodiment of the prior art;

FIG. 5 is a section view of a plan identified as A-A′ in FIG. 1 of a third embodiment of the prior art;

FIG. 6 is a section view of a plan identified as A-A′ in FIG. 1 of a fourth embodiment of the prior art;

FIG. 7 is a section view of a plan identified as A-A′ in FIG. 1 of a fifth embodiment of the prior art;

FIG. 8 is a section view of a first embodiment of an inventive semiconductor arrangement, taken along a section plane identified with A-A′ in FIG. 1;

FIG. 9 is a section view of a second embodiment of the inventive semiconductor arrangement along a section plane identified as A-A′ in FIG. 1; and

FIG. 10 is a section view of a third embodiment of an inventive semiconductor arrangement along a section plane identified with a A-A′ in FIG. 1.

### DESCRIPTION OF THE PREFERRED EMBODIMENTS

In the following description of the embodiments of the present invention identical or comparable components are identified with the same reference numerals.

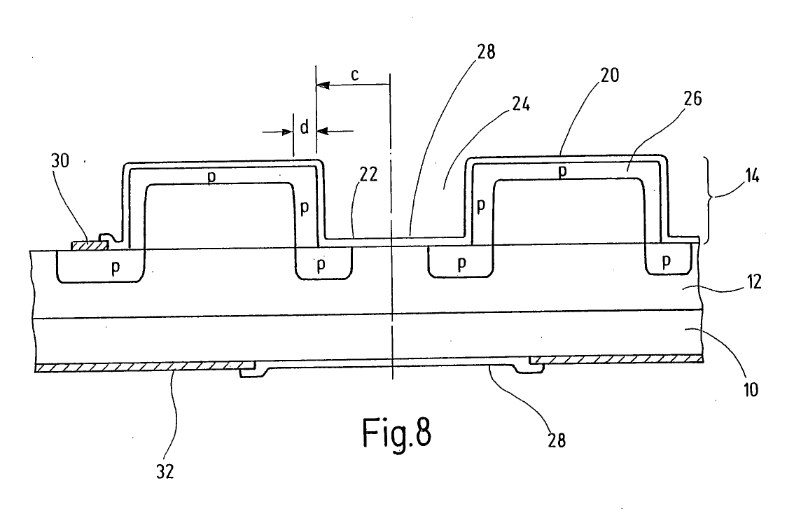

FIG. 8 shows a sectional view of a first embodiment of the present invention. The section plane corresponds to the section plan which is identified with the line A-A′ in FIG. 1. It can be seen that the p-doped regions 150 in FIG. 1 do not correspond to the p-doped regions of FIG. 8. The arrangement in accordance with FIG. 8 includes a support substrate 10 of n⁺-InP. Moreover, a layer 12 of n-InP is arranged over it. In InGaAs layer 14 is superposed on the layer 12. The InGaAs layer 14 is structured. The structuring can be performed by selective, or in other words local removal of the layer in a first masking step. In a second masking step subsequently a p-doping 26 is introduced. The introduction of the p-doping 26 can be performed for example by a selective diffusion. The zone with p-conductivity extends over the upper surface of the InGaAs layer 14, as well as over the flank of the InGaAs layer 14 which surrounds the interruption 24 until in an upper surface region of the InP layer 12.

The upper surfaces of the arrangement are covered partially by antireflection layers 28 for reducing losses by a reflection. A p-contact 30 is arranged on the InP layer 12 in the region of the p-conductivity. The n-contact 32 is arranged on the substrate layer 10.

When the layer arrangement in accordance with FIG. 8 is utilized as an optical detector for example in a wavelength region of 1064 nm, then the InGaAs layer 14 is absorbing, while the InP layers 10, 12 are light-permeable. Thereby the interruption 24 corresponds to a light-permeable zone 22. The regions of the layer 14 which surround the interruption 24 act as an absorbing zone 20.

The effective transition region between the transparent zone 22 and the active absorbing zone 20, or in other words the part of the absorbing zone 20, in which a light impingement for production of a photo current occurs is determined substantially by the width of the p-doping in the flank region that surrounds the interruption 24. The penetration depth of the p-doping d can in general be substantially smaller than 10 μm, wherein the typical values are in the region between 0.5 μm and 1 μm.

In connection with an eccentricity of the arrangement, it is considered as specially advantageous when the absorbing zone 20 and the light-permeable zone 22 are defined in a single masking layer, namely during removal of the absorbing layer for producing the interruption 24. It is also advantageous when in the same masking step raised portions are produced in the layer 14. Such so-called metering can be used as pattern structures for mounting on a support for precise passive adjustment. It can be used for exact orientation on a subsequent optical processing unit.

In the second masking step, or in other words in which the p-conductivity is introduced in the upper surface of the layers 14, 12, the accurate masking layer for definition of the photo-sensitive region is not critical. This is a further advantage in view of a precision of an optical detector, in which an arrangement in accordance with FIG. 8 is utilized.

FIG. 8 represents also a further aspect of an inventive optical detector. The section view shown in FIG. 8 can correspond to a section along a plane, which corresponds to a plane identified with a line B-B′ in FIG. 1. In this case in this region a raise of the leakage current is avoided.

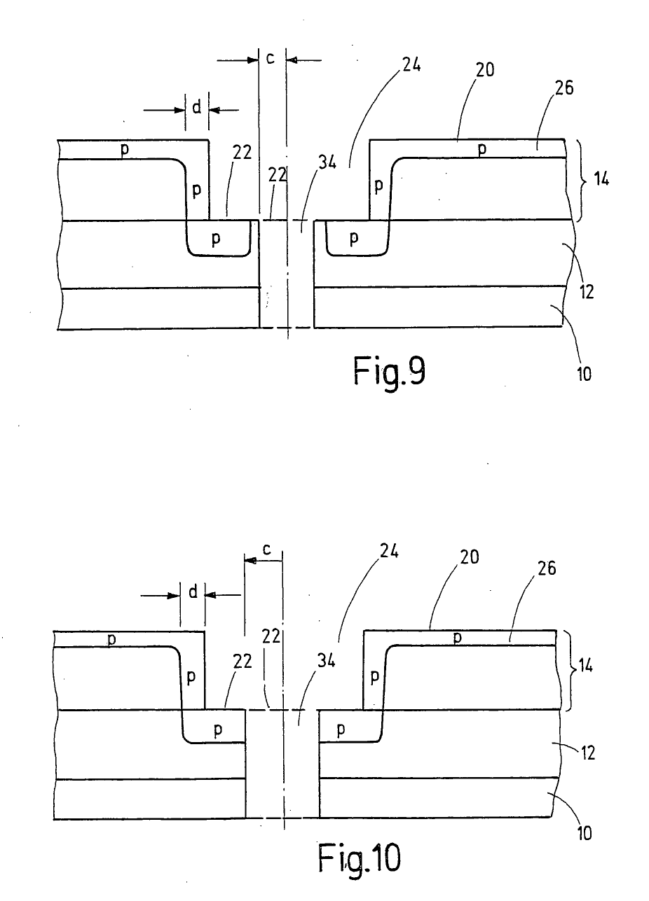

FIG. 9 shows an arrangement which corresponds substantially to the arrangement of FIG. 8. In contrast to FIG. 8, in the shown part of the arrangement the layer 14 is removed only in the region of the interruption 24. A further difference when compared to FIG. 8 is that for improving the transparency of the light-permeable zone 22, a throughgoing opening 24 is provided in the layers 10, 12. Also in the arrangement of FIG. 9 antireflection layers can be provided, which are not explicitedly shown for the sake of observation, as well as the p- and n-contacts.

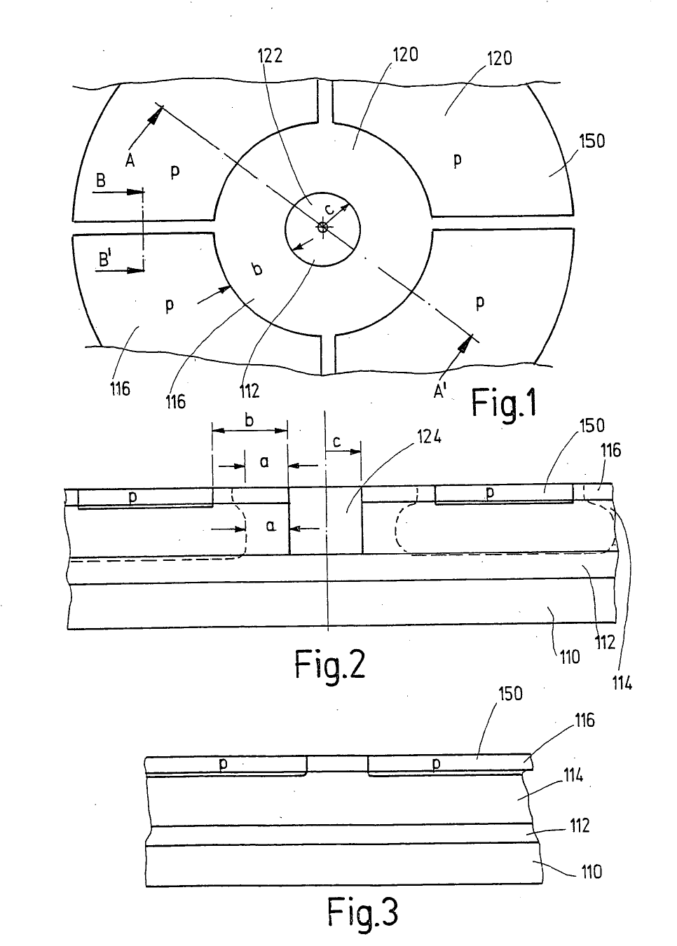

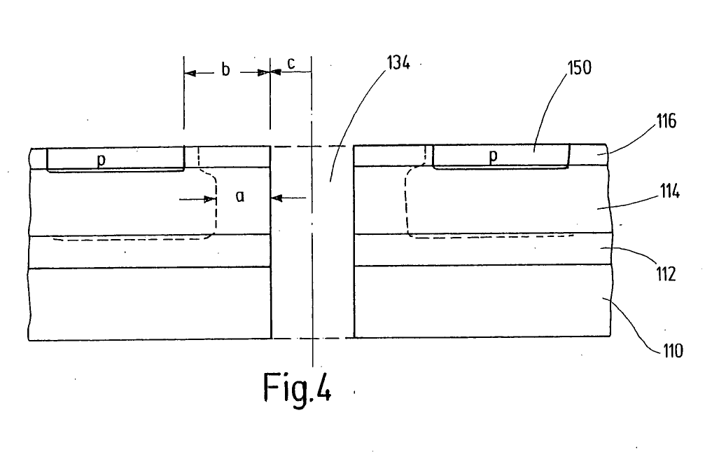

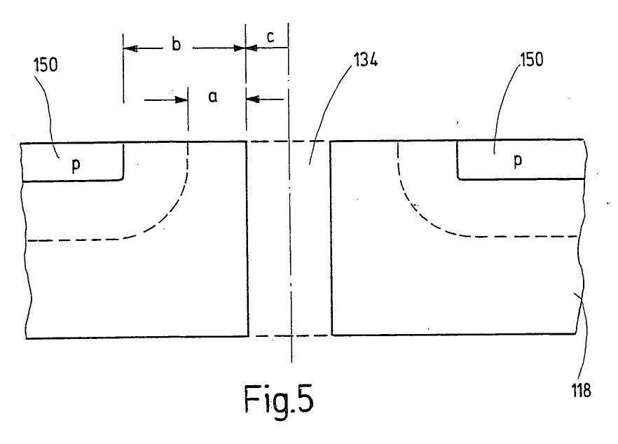

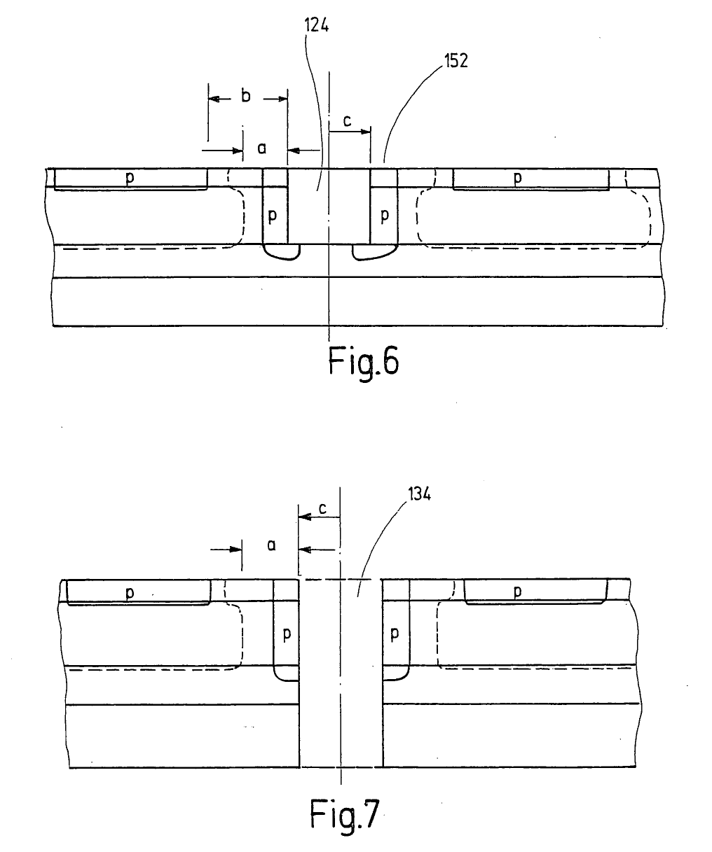

FIG. 10 substantially corresponds to FIG. 9. In contrast to FIG. 9, in FIG. 2 the p-doped region 26 extends up to the throughgoing opening 34, which in the embodiment of FIG. 10 has a greater radius c than in the arrangement of FIG. 9. Also, in the arrangement in accordance with FIG. 10 antireflection layers can be provided. Also, for the purpose of better observation the n- and p-contacts are not explicitly illustrated.

It will be understood that each of the elements described above, or two or more together, may also find a useful application in other types of constructions differing from the types described above.

While the invention has been illustrated and described as embodied in optical detector and method of producing an arrangement multiple semiconductor layers, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims:

1-10. (canceled)

11. A method of producing an arrangement of several semiconductor layers, comprising the steps of forming at least one absorbing zone in a predetermined wavelength region; forming at least one light-permeable zone in the at least one predetermined wavelength region; forming a semiconductor layer located under it and that in the predetermined wavelength region is at least partially light-permeable region; realizing the at least one light-permeable zone by an interruption of the absorbing semiconductor layer; producing the interruption of the absorbing semiconductor layer by a local removal of the absorbing semiconductor layer; and introducing a throughgoing doing in an upper surface of the absorbing semiconductor layer that surrounds the interruption and in at least a part of an upper surface of the at least partially light-permeable semiconductor layer.

12. A method as defined in claim 11; and further comprising performing a local removal of the absorbing layer in a first masking step; and performing the doping in a second masking step.

13. A method as defined in claim 11; and further comprising performing a doping by a selective diffusion.

14. A method as defined in claim 11; and further comprising thinning the at least partially light-permeable semiconductor layer.

15. A method as defined in claim 1; and further comprising introducing a throughgoing opening in the at least partially light-permeable semiconductor layer in a region of the interruption of the absorbing semiconductor layer.

16. A method as defined in claim 15; and further comprising performing the introducing of the throughgoing opening by an etching process.

17. A method as defined in claim 15; and further comprising performing the introducing of the throughgoing opening by a laser cutting technique.

18. A method as defined in claim 11; and further comprising providing upper surfaces of the arrangement of several semiconductor layer at least partially with an antireflection layer.

19. A method as defined in claim 11; and further comprising providing an inclination of flanks in a region of the interruption by a process selected from the group consisting of a crystal orientation, structuring, and both.

20. A method as defined in claim 11; and further comprising using InGaAs as the absorbing semiconductor layer; and using InP as the at least partially light-permeable semiconductor layer.

21. A method as defined in claim 11; and further comprising applying a p-contact on the throughgoing p-doping; and applying an n-contact on the n-doped partially light-permeable semiconductor layer.

22-25. (canceled)
